(19) United States
(12) Patent Application Publication
(10) Pub. No.: US 2023/0170872 A1
(43) Pub. Date: Jun. 1, 2023

(54) BULK-ACOUSTIC WAVE RESONATOR

(71) Applicant: SAMSUNG ELECTRO-MECHANICS CO., LTD., Suwon-si (KR)

(72) Inventors: Sang Heon HAN, Suwon-si (KR); Sang Uk SON, Suwon-si (KR)

(73) Assignee: SAMSUNG ELECTRO-MECHANICS CO., LTD., Suwon-si (KR)

(21) Appl. No.: 17/889,710

(22) Filed: Aug. 17, 2022

(30) Foreign Application Priority Data
Nov. 29, 2021 (KR) 10-2021-0167235

(51) Int. Cl. H03H 9/02; H03H 9/13; H03H 9/17

(52) U.S. Cl. CPC H03H 9/02015; H03H 9/02086; H03H 9/132; H03H 9/171; H03H 9/131

(57) ABSTRACT

A bulk-acoustic wave resonator includes a substrate, a resonance portion including a first electrode, a piezoelectric layer, and a second electrode, stacked in this order on the substrate, and a seed layer disposed below the first electrode, wherein the resonance portion includes an active portion disposed in a central portion of the resonance portion, and a lateral resonance suppressing portion disposed to surround the active portion, wherein a thickness distribution of the seed layer, the first electrode, the piezoelectric layer, and the second electrode in the lateral resonance suppressing portion is different from a thickness distribution in the active portion.

### CROSS-REFERENCE TO RELATED APPLICATIONS

This application claims the benefit under 35 USC 119(a) of Korean Patent Application No. 10-2021-0167235 filed on Nov. 29, 2021, in the Korean Intellectual Property Office, the entire disclosure of which is incorporated herein by reference for all purposes.

### BACKGROUND

### 1. Field

The present disclosure relates to a bulk-acoustic wave resonator.

### 2. Description of the Background

In accordance with the trend for miniaturization of wireless communications devices, there has been increasing demand for miniaturization of high-frequency components, and for example, a bulk-acoustic wave resonator (BAW) type filter based on the technique of manufacturing a semiconductor thin film wafer may be used.

A bulk-acoustic wave resonator (BAW) may refer to a thin film device configured as a filter, which may induce resonance using piezoelectric properties by depositing a piezoelectric dielectric material on a silicon wafer, which may be a semiconductor support substrate.

Recently, interest in 5G communications technology has been increasing, and development of acoustic resonator technology that may be implemented in a candidate band has been actively conducted. In addition, research on various structural shapes and functions to improve characteristics and performance of a bulk-acoustic wave resonator has been conducted, and accordingly continuous research of manufacturing methods has also been undertaken.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a bulk-acoustic wave resonator includes a substrate, a resonance portion including a first electrode, a piezoelectric layer, and a second electrode, stacked in this order on the substrate, and a seed layer disposed below the first electrode, wherein the resonance portion includes an active portion disposed in a central portion of the resonance portion, and a lateral resonance suppressing portion disposed to surround the active portion, wherein a thickness distribution of the seed layer, the first electrode, the piezoelectric layer, and the second electrode in the lateral resonance suppressing portion is different from a thickness distribution in the active portion.

A thickness of at least one of the first electrode and the second electrode in the lateral resonance suppressing portion may be thinner than a thickness of the at least one of the first electrode and the second electrode in the active portion.

A thickness of the seed layer in the lateral resonance suppressing portion may be thicker than a thickness of the seed layer in the active portion.

The seed layer in the lateral resonance suppressing portion may protrude toward the first electrode, and a distance from which the seed layer protrudes may be 100 Å to 230 Å.

A width of the lateral resonance suppressing portion may be 2.6 μm to 6.2 μm.

A thickness of the piezoelectric layer in the lateral resonance suppressing portion may be thicker than a thickness of the piezoelectric layer in the active portion.

The resonance portion may further include an expansion portion disposed to surround the lateral resonance suppressing portion, and the expansion portion may include an insertion layer disposed between the first electrode and the second electrode.

The insertion layer may be disposed between the first electrode and the piezoelectric layer or between the piezoelectric layer and the second electrode.

A thickness of the seed layer in the lateral resonance suppressing portion may be equal to a thickness of the seed layer in the expansion portion.

The piezoelectric layer may include a first piezoelectric layer stacked on the first electrode, and a second piezoelectric layer stacked on the first piezoelectric layer, and the first piezoelectric layer and the second piezoelectric layer may be formed of different materials.

The piezoelectric layer may further include a third piezoelectric layer stacked on the second piezoelectric layer, and the third piezoelectric layer may be formed of the same material as the first piezoelectric layer.

In another general aspect, a bulk-acoustic wave resonator includes a substrate, and a resonance portion including a plurality of thin film layers stacked on the substrate, wherein the resonance portion includes an active portion disposed in a central portion of the resonance portion, and a lateral resonance suppressing portion disposed to surround the active portion, wherein an overall thickness of a thin film layer formed of a metal material, among the plurality of thin film layers, in the lateral resonance suppressing portion is thinner than an overall thickness of the thin film layer in the active portion, and wherein a difference in thickness of the thin film layer is 100 Å to 230 Å.

The plurality of thin film layers may include a seed layer and a first electrode stacked on the seed layer, and the seed layer in the lateral resonance suppressing portion may protrude toward the first electrode.

An overall thickness of the seed layer and the first electrode in the lateral resonance suppressing portion may be equal to an overall thickness of the seed layer and the first electrode in the active portion.

The plurality of thin film layers may include a first electrode, a piezoelectric layer, and a second electrode, stacked in this order, and the piezoelectric layer in the lateral resonance suppressing portion may protrude toward the first electrode or the second electrode.

An overall thickness of the first electrode, the piezoelectric layer, and the second electrode in the lateral resonance suppressing portion may be equal to an overall thickness of the first electrode, the piezoelectric layer, and the second electrode in the active portion.

In another general aspect, a bulk acoustic wave resonator includes a plurality of layers including a seed layer, a first electrode, a piezoelectric layer, and a second electrode disposed in this order in a thickness direction on a substrate, wherein one or more of the plurality of layers includes a protrusion in the thickness direction disposed in a lateral resonance suppressing portion, and wherein the plurality of layers include a same thickness in an active portion adjacent to the lateral resonance suppressing portion as in the lateral resonance suppressing portion.

A thickness of at least one of the first electrode and the second electrode in the lateral resonance suppressing portion may be less than a thickness of the at least one of the first electrode and the second electrode in the active portion.

The bulk-acoustic wave resonator may further include an insertion layer disposed between the first electrode and the second electrode in an expansion portion, wherein the lateral resonance suppressing portion is disposed between the active portion and the expansion portion.

The lateral resonance suppressing portion width may be in a range of about 2 μm to 6.2 μm.

The protrusion may be in a range of about 5% to 10% of the thickness of the first electrode.

Other features and aspects will be apparent from the following detailed description, the drawings, and the claims.

### BRIEF DESCRIPTION OF DRAWINGS

FIG. 1 is a plan view of a bulk-acoustic wave resonator according to an embodiment of the present disclosure.

FIG. 2 is a cross-sectional view taken along line I-I′ in FIG. 1.

FIG. 3 is a cross-sectional view taken along line II-II′ in FIG. 1.

FIG. 4 is a cross-sectional view taken along line III-III′ in FIG. 1.

FIG. 5 is a graph measuring loss characteristics according to a width and a thickness of a lateral resonance suppressing portion.

FIG. 6 is a cross-sectional view schematically illustrating a bulk-acoustic wave resonator according to another embodiment of the present disclosure.

FIG. 7 is a cross-sectional view schematically illustrating a bulk-acoustic wave resonator according to still another embodiment of the present disclosure.

FIG. 8 is a cross-sectional view schematically illustrating a bulk-acoustic wave resonator according to still another embodiment of the present disclosure.

FIG. 9 is a cross-sectional view schematically illustrating a bulk-acoustic wave resonator according to still another embodiment of the present disclosure.

FIG. 10 is a cross-sectional view schematically illustrating a bulk-acoustic wave resonator according to still another embodiment of the present disclosure.

FIG. 11 is a cross-sectional view schematically illustrating a bulk-acoustic wave resonator according to still another embodiment of the present disclosure.

FIG. 12 is a cross-sectional view schematically illustrating a bulk-acoustic wave resonator according to still another embodiment of the present disclosure.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

Hereinafter, while example embodiments of the present disclosure will now be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

An aspect of the present disclosure is to provide an acoustic resonator having improved performance.

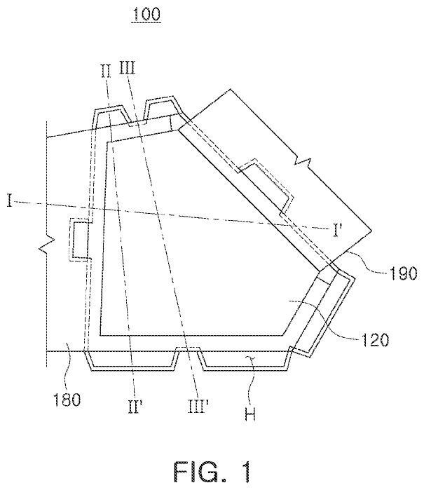

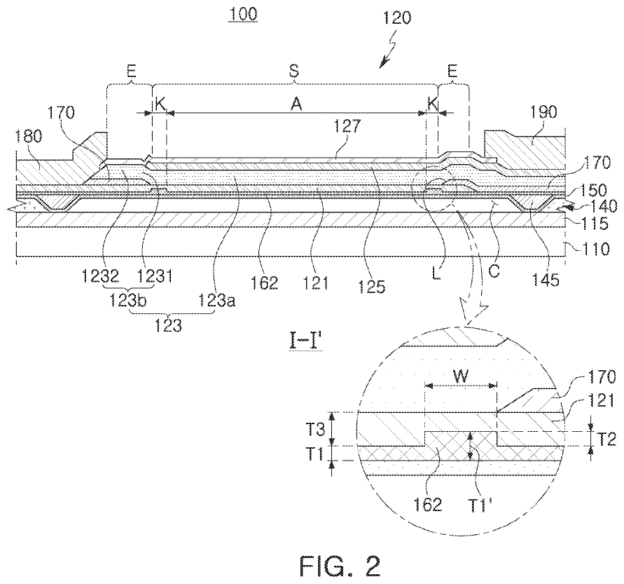

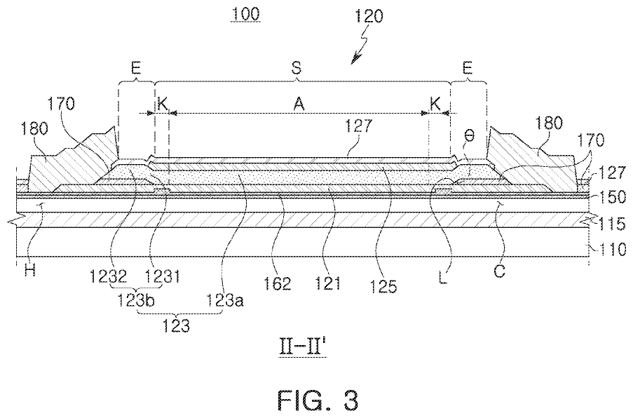

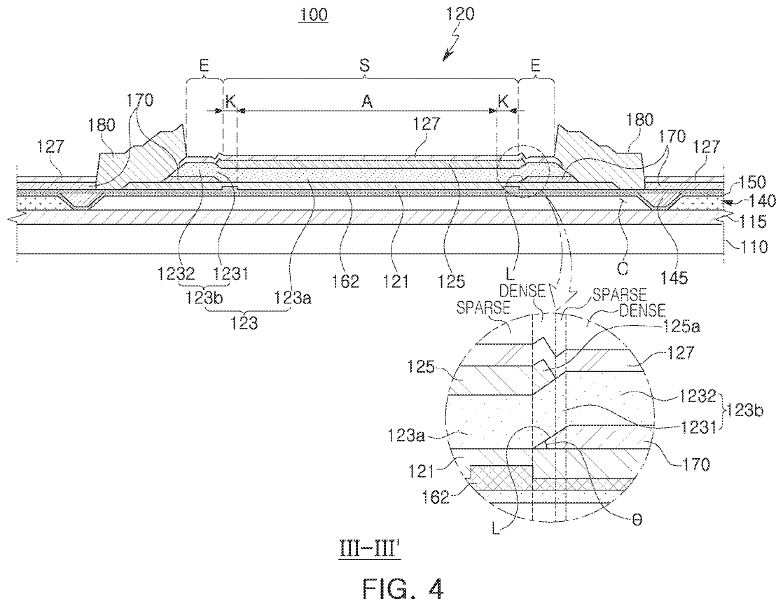

FIG. 1 is a plan view of a bulk-acoustic wave resonator according to an embodiment of the present disclosure, and FIG. 2 is a cross-sectional view taken along line I-I′ in FIG. 1. FIG. 3 is a cross-sectional view taken along line II-II′ in FIG. 1, and FIG. 4 is a cross-sectional view taken along line III-III′ in FIG. 1.

Referring to FIGS. 1 to 4, an acoustic resonator 100 in an embodiment of the present disclosure may be implemented as a bulk-acoustic wave resonator (BAW), and may include a substrate 110, a support layer 140, a resonance portion 120, and an insertion layer 170.

The substrate 110 may be configured as a silicon substrate. For example, a silicon wafer or a silicon-on-insulator (SOI) type substrate may be used as the substrate 110.

An insulating layer 115 may be disposed on an upper surface of the substrate 110, and may electrically isolate the substrate 110 from the resonance portion 120. Also, the insulating layer 115 may prevent the substrate 110 from being etched by an etching gas, when a cavity C is formed during a process of manufacturing the acoustic wave resonator.

In this case, the insulating layer 115 may be formed of at least one of silicon dioxide (SiO₂), silicon nitride (Si₃N₄), aluminum oxide (Al₂O₃), or aluminum nitride (AlN), and may be formed by one of chemical vapor deposition, RF magnetron sputtering, or evaporation.

The support layer 140 may be formed on the insulating layer 115, and may be disposed around the cavity C and an etch stop portion 145 by surrounding the cavity C and the etch stop portion 145.

The cavity C may be formed as a void, and may be formed by removing a portion of a sacrificial layer formed in the process of preparing the support layer 140.

The etch stop portion 145 may be disposed along a boundary of the cavity C. The etch stop portion 145 may be provided to prevent etching beyond a region for a cavity during a process of forming the cavity C.

A membrane layer 150 may be formed on the support layer 140, and may form an upper surface of the cavity C. Therefore, the membrane layer 150 may also be formed of a material not easily removed in the process of forming the cavity C.

For example, when a halide-based etching gas such as fluorine (F), chlorine (Cl), or the like is used to remove a portion (e.g., the region for cavity) of the support layer 140, the membrane layer 150 may be formed of a material having low reactivity with the etching gas. In this case, the membrane layer 150 may include at least one of silicon dioxide (SiO₂) or silicon nitride (Si₃N₄).

In addition, the membrane layer 150 may be configured as a dielectric layer including at least one material of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), or zinc oxide (ZnO), or may be configured as a metal layer including at least one material of aluminum (Al), nickel (Ni), chromium (Cr), platinum (Pt), gallium (Ga), or hafnium (Hf). However, a configuration of the present disclosure is not limited thereto.

The resonance portion 120 may include a first electrode 121, a piezoelectric layer 123, and a second electrode 125. In the resonance portion 120, the first electrode 121, the piezoelectric layer 123, and the second electrode 125 may be stacked in this order from the bottom. Therefore, in the resonance portion 120, the piezoelectric layer 123 may be disposed between the first electrode 121 and the second electrode 125.

Since the resonance portion 120 is formed on the membrane layer 150, the membrane layer 150, the first electrode 121, the piezoelectric layer 123 and the second electrode 125 may be stacked to form the resonance portion 120.

The resonance portion 120 may generate a resonant frequency and an anti-resonant frequency by resonating the piezoelectric layer 123 in response to a signal applied to the first electrode 121 and the second electrode 125.

As illustrated in FIG. 2, the resonance portion 120 may be divided into a central portion S and an expansion portion E in a width direction.

The central portion S may be a region in which the first electrode 121, the piezoelectric layer 123, and the second electrode 125 are stacked to be approximately flat, and may be a resonant active region in which resonance is substantially generated.

The expansion portion E may be a region extending from the central portion S to the outside of the central portion S, and may be a region in which the insertion layer 170 is interposed between the first electrode 121 and the piezoelectric layer 123. More specifically, the expansion portion E may be a region in which the first electrode 121, the insertion layer 170, the piezoelectric layer 123, and the second electrode 125 are stacked.

A lateral resonance suppressing portion K may be formed in the central portion S.

The lateral resonance suppressing portion K may be disposed in the central portion S, and may be a ring-shaped region formed along a circumference of the central portion S with a predetermined width. The lateral resonance suppressing portion K may be provided to suppress spurious vibrations, which may be unnecessary vibrations generated in the resonance portion 120, which will be described later.

Based on a boundary between the central portion S and the expansion portion E, the lateral resonance suppressing portion K may be formed in a continuous ring shape along the boundary from an inside of the central portion S, and the expansion portion E may be formed in a continuous ring shape along the boundary from an outside of the central portion S. However, as necessary, some regions may be configured in a discontinuous ring shape.

Therefore, as illustrated in FIG. 2, on a cross-sectional surface of the resonance portion 120 crossing the central portion S, the expansion portion E may be disposed on each of both ends of the central portion S. Also, the insertion layer 170 may be disposed on each of both sides of the expansion portion E disposed on both ends of the central portion S.

The insertion layer 170 may include an inclined surface L having a thickness increasing in a direction away from the central portion S.

In the expansion portion E, the piezoelectric layer 123 and the second electrode 125 may be disposed on the insertion layer 170. Therefore, the piezoelectric layer 123 and the second electrode 125 disposed in the expansion portion E may have an inclined surface along a shape of the insertion layer 170.

In the present embodiment, the expansion portion E may be defined to be included in the resonance portion 120, and accordingly, resonance may be performed in the expansion portion E as well. However, the present disclosure is not limited thereto, and, resonance may not be performed in the expansion portion E, and resonance may be performed only in the central portion S, depending on a structure of the expansion portion E.

The first electrode 121 and the second electrode 125 may be formed of a conductor, and may be formed of gold, molybdenum, ruthenium, iridium, aluminum, platinum, titanium, tungsten, palladium, tantalum, chromium, nickel, or a metal including at least one of the above-mentioned elements, but the present disclosure is not limited thereto.

In the resonance portion 120, the first electrode 121 may be configured to have an area larger than the second electrode 125, and a first metal layer 180 may be disposed on the first electrode 121 along an outer edge of the first electrode 121. Therefore, the first metal layer 180 may be spaced apart from the second electrode 125 by a predetermined distance, and may be disposed to surround the resonance portion 120.

Since the first electrode 121 is disposed on the membrane layer 150, the first electrode 121 may be formed to be flat. Since the second electrode 125 is disposed on the piezoelectric layer 123, a curve may be formed to correspond to a shape of the piezoelectric layer 123.

The first electrode 121 may be used as one of an input electrode and an output electrode for inputting and outputting an electrical signal such as a radio frequency (RF) signal or the like.

A seed layer 162 may be disposed below the first electrode 121. Specifically, the seed layer 162 may be disposed between the first electrode 121 and the membrane layer 150 to function as a seed for forming the first electrode.

The seed layer may be formed of aluminum nitride (AlN). Also, when the first electrode is formed of molybdenum (Mo), the seed layer 162 may be formed of a metal having a hexagonal closed-packed (HCP) crystal structure, such as titanium (Ti). In this case, a lattice mismatch with the first electrode 121 may be reduced.

The second electrode 125 may be entirely disposed in the central portion S, and may be partially disposed in the expansion portion E. Therefore, the second electrode 125 may be divided into a portion disposed on a piezoelectric portion 123a of the piezoelectric layer 123, and a portion disposed on a bent portion 123b of the piezoelectric layer 123.

More specifically, in the embodiment, the second electrode 125 may be disposed to cover the entire piezoelectric portion 123a and a portion of an inclined portion 1231 of the piezoelectric layer 123. Therefore, a second electrode (125a in FIG. 4) disposed in the expansion portion E may have an area smaller than an area of an inclined surface of the inclined portion 1231, and the second electrode 125 in the resonance portion 120 may have an area smaller than an area of the piezoelectric layer 123.

Therefore, as illustrated in FIG. 2, on the cross-sectional surface of the resonance portion 120 crossing the central portion S, an end of the second electrode 125 may be disposed in the expansion portion E. Also, an end of the second electrode 125 disposed in the expansion portion E may partially overlap the insertion layer 170. In this case, a configuration in which the expansion portion E may partially overlap the insertion layer 170 indicates that, when the second electrode 125 is projected on a plane on which the insertion layer 170 is disposed, a shape of the second electrode 125 projected on the plane may overlap the insertion layer 170. Therefore, the end of the second electrode 125 may be disposed on the inclined portion.

The second electrode 125 may be used as one of an input electrode and an output electrode for inputting and outputting an electrical signal such as a radio frequency (RF) signal or the like. For example, when the first electrode 121 is used as an input electrode, the second electrode 125 may be used as an output electrode, and when the first electrode 121 is used as an output electrode, the second electrode 125 may be used as an input electrode.

As illustrated in FIG. 4, when the end of the second electrode 125 is disposed on the inclined portion 1231 of the piezoelectric layer 123, a local structure of acoustic impedance of the resonance portion 120 may be formed in a sparse/dense/sparse/dense structure from the central portion S, such that a reflective interface for reflecting a lateral wave into the resonance portion 120 may increase. Therefore, most of lateral waves may not escape the resonance portion 120, and may be reflected into the resonance portion 120, such that performance of the bulk-acoustic wave resonator may be improved.

The piezoelectric layer 123 may be configured to generate a piezoelectric effect of converting electrical energy into mechanical energy in the form of acoustic waves, and may be formed on the first electrode 121 and the insertion layer 170.

As a material of the piezoelectric layer 123, zinc oxide (ZnO), aluminum nitride (AlN), doped aluminum nitride, lead zirconate titanate (PZT), quartz, or the like may be used. The doped aluminum nitride may further include a rare earth metal, a transition metal, or an alkaline earth metal. The rare earth metal may include at least one of scandium (Sc), erbium (Er), yttrium (Y), or lanthanum (La). The transition metal may include at least one of hafnium (Hf), titanium (Ti), zirconium (Zr), tantalum (Ta), or niobium (Nb). The alkaline earth metal may include magnesium (Mg).

When the content of elements doped into aluminum nitride (AlN) to improve piezoelectric properties is less than 0.1 at %, piezoelectric properties higher than that of aluminum nitride (AlN) may not be implemented, and when the content of elements exceeds 30 at %, manufacturing and composition control for deposition may be difficult such that a non-uniform phase may be formed.

Therefore, in the present embodiment, the content of elements doped into aluminum nitride (AlN) may be in the range of 0.1 to 30 at %.

In the present embodiment, aluminum nitride (AlN) doped with scandium (Sc) may be used for the piezoelectric layer. In this case, a piezoelectric constant may increase such that kt² of the acoustic wave resonator may increase.

The piezoelectric layer 123 according to the present embodiment may include a piezoelectric portion 123a disposed in the central portion S, and a bent portion 123b disposed in the expansion portion E.

The piezoelectric portion 123a may be configured to be directly stacked on the upper surface of the first electrode 121. Therefore, the piezoelectric portion 123a may be interposed between the first electrode 121 and the second electrode 125, and may be formed to be flat along with the first electrode 121 and the second electrode 125.

The bent portion 123b may be defined as a region extending outwardly from the piezoelectric portion 123a and disposed in the expansion portion E.

The bent portion 123b may be disposed on the insertion layer 170, and may have a shape in which the upper surface thereof may be raised along a shape of the insertion layer 170. Therefore, the piezoelectric layer 123 may be bent on a boundary between the piezoelectric portion 123a and the bent portion 123b, and the bent portion 123b may be raised to correspond to a thickness and a shape of the insertion layer 170.

The bent portion 123b may be divided into an inclined portion 1231 and an extended portion 1232.

The inclined portion 1231 may refer to a portion formed to be inclined along the inclined surface L of the insertion layer 170. Also, the extended portion 1232 may refer to a portion extending outwardly from the inclined portion 1231.

The inclined portion 1231 may be formed parallel to the inclined surface L of the insertion layer 170, and an inclination angle of the inclined portion 1231 may be formed to be the same as an inclination angle of the inclined surface L of the insertion layer 170.

The insertion layer 170 may be disposed between the first electrode 121 and the second electrode 125, and, in the present embodiment, may be disposed along a surface formed by the membrane layer 150, the first electrode 121, and the etch stop portion 145. Therefore, the insertion layer 170 may be partially disposed in the resonance portion 120, and may be disposed between the first electrode 121 and the piezoelectric layer 123.

The insertion layer 170 may be disposed on a periphery of the central portion S, and may support the bent portion 123b of the piezoelectric layer 123. Therefore, the bent portion 123b of the piezoelectric layer 123 may be divided into the inclined portion 1231 and the extended portion 1232, according to a shape of the insertion layer 170.

In the present embodiment, the insertion layer 170 may be disposed in a region other than the central portion S. For example, the insertion layer 170 may be disposed on the entire region other than the central portion S on the substrate 110, or may be partially disposed on a region thereof.

A side surface of the insertion layer 170 disposed adjacent to the central portion S may be formed as an inclined surface L having a constant inclination angle θ. For this reason, the insertion layer 170 may be configured to have a thickness increasing in a direction away from the central portion S.

When the inclination angle θ of the side surface of the insert layer 170 is smaller than 5°, to prepare such a configuration, a thickness of the insert layer 170 may need to be significantly reduced or an area of the inclined surface L may need to be excessively increased, which may be difficult to implement.

Also, when the inclination angle θ of the side surface of the insertion layer 170 is greater than 70°, an inclination angle of the piezoelectric layer 123 or the second electrode 125 stacked on the insertion layer 170 may be greater than 70°. In this case, since the piezoelectric layer 123 or the second electrode 125 stacked on the inclined surface L is excessively bent, cracks may be created in the bent portion.

Therefore, in the present embodiment, the inclination angle θ of the inclined surface L may be formed in the range of 5° or more and 70° or less.

In the present embodiment, the inclined portion 1231 of the piezoelectric layer 123 may be formed along the inclined surface L of the insertion layer 170, and may thus have the same inclination angle as that of the inclined surface L of the insertion layer 170. Therefore, the inclination angle of the inclined portion 1231 may also be formed in the range of 5° or more and 70° or less, similarly to the inclined surface L of the insertion layer 170. This configuration may be equally applied to the second electrode 125 stacked on the inclined surface L of the insertion layer 170.

The insertion layer 170 may be formed of a dielectric material such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), or the like, and may be formed of a material different from that of the piezoelectric layer 123.

Also, the insertion layer 170 may be implemented by a metal material. When the bulk-acoustic wave resonator in the present embodiment is used for 5G communications, since heat may be extensively generated in a resonator, it may be necessary to smoothly radiate the heat generated in the resonance portion 120. To this end, the insertion layer 170 in the present embodiment may be formed of an aluminum alloy material including scandium (Sc).

Also, the insertion layer 170 may be formed as a SiO₂ thin film implanted with nitrogen (N) or fluorine (F).

As the insertion layer 170 is provided, the expansion portion E may be formed to be thicker than the central portion S. Therefore, the expansion portion E may function as a frame reflecting a horizontal acoustic wave toward the outside of the resonance portion 120, among the horizontal acoustic waves generated in the central portion S, toward the central portion S, to reduce energy loss of the elastic wave. Therefore, a high Q-factor, kt² may be secured.

A high Q-factor may improve blocking characteristics of other frequency bands when implementing a filter or a duplexer, and a high kt² may secure a bandwidth to increase a data transmission amount and speed during data transmission and reception.

The resonance portion 120 may be spaced apart from the substrate 110 through the cavity C formed as a void.

The cavity C may be formed by removing a portion of the support layer 140 by supplying an etching gas (or an etching solution) to an inlet hole (H in FIG. 1) during the process of manufacturing the acoustic wave resonator.

A protective layer 127 may be disposed along the surface of the acoustic wave resonator 100, and may protect the acoustic wave resonator 100. The protective layer 127 may be disposed along a surface formed by the second electrode 125 and the bent portion 123b of the piezoelectric layer 123.

The protective layer 127 may be formed as a single layer, or may be formed by stacking two or more layers having different materials, as desired. Also, the protective layer 127 may be partially removed for frequency control in a final process. For example, a thickness of the protective layer 127 may be adjusted in a frequency trimming process.

As the protective layer 127, a dielectric layer including one of silicon nitride (Si₃N₄), silicon oxide (SiO₂), magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), or zinc oxide (ZnO) may be used, but the present disclosure is not limited thereto.

The first electrode 121 and the second electrode 125 may extend externally of the resonance portion 120. Also, a first metal layer 180 and a second metal layer 190 may be disposed on the upper surfaces of the extended portions, respectively.

The first metal layer 180 and the second metal layer 190 may be formed of one of gold (Au), a gold-tin (Au—Sn) alloy, copper (Cu), a copper-tin (Cu—Sn) alloy, aluminum (Al), or an aluminum alloy. In this case, the aluminum alloy may be an aluminum-germanium (Al—Ge) alloy or an aluminum-scandium (Al—Sc) alloy.

The first metal layer 180 and the second metal layer 190 may function as a connection wiring electrically connect the electrodes 121 and 125 of the acoustic wave resonator in the present embodiment to electrodes of another acoustic wave resonator disposed adjacent to the acoustic wave resonator and on the substrate 110.

The first metal layer 180 may penetrate a protective layer 127, and may be bonded to the first electrode 121.

Also, in the resonance portion 120, the first electrode 121 may have an area larger than that of the second electrode 125, and the first metal layer 180 may be formed on a peripheral portion of the first electrode 121.

Therefore, the first metal layer 180 may be disposed along the periphery of the resonance portion 120, and may surround the second electrode 125. However, the present disclosure is not limited thereto.

In addition, in the present embodiment, at least a portion of the protective layer 127 located on the resonance portion 120 may be disposed to contact the first metal layer 180 and the second metal layer 190. Since the first metal layer 180 and the second metal layer 190 may be formed of a metal material having high thermal conductivity, and may have a large volume, a large heat dissipation effect may be provided.

Therefore, to rapidly transfer heat generated in the piezoelectric layer 123 to the first metal layer 180 and the second metal layer 190 via the protective layer 127, the protective layer 127 may be connected to the first metal layer 180 and the second metal layer 190.

In the present embodiment, at least a portion of the protective layer 127 may be disposed below the first metal layer 180 and the second metal layer 190. Specifically, the protective layer 127 may be disposed between the first metal layer 180 and the piezoelectric layer 123, between the second metal layer 190 and the piezoelectric layer 123, and between the second metal layer 190 and the second electrode 125, respectively.

The resonance portion 120 configured as above may be spaced apart from the substrate 110 through the cavity C disposed below the membrane layer 150. Therefore, the membrane layer 150 may be disposed below the first electrode 121 and the insertion layer 170, and may support the resonance portion 120.

The cavity C may be formed as a void, and may be formed by removing a portion of the support layer 140 by supplying an etching gas (or an etching solution) to an inlet hole (H in FIG. 1).

As described above, in the bulk-acoustic wave resonator according to the present embodiment, a lateral resonance suppressing portion K may be disposed in the resonance portion 120 to suppress spurious vibrations, which may be unnecessary vibrations.

In the present embodiment, the central portion S may be divided into an active portion A disposed in a central region, and a lateral resonance suppressing portion K disposed around the active portion A.

The lateral resonance suppressing portion K may extend from the active portion A, and may have a thickness structure of each of the stacked layers, different from that of the active portion A. Specifically, the lateral resonance suppressing portion K may be defined as a region in which a thickness of at least one of a plurality of thin film layers including the seed layer 162, the first electrode 121, the piezoelectric layer 123, and the second electrode 125 is formed differently from those in the active portion A. Specifically, a thickness distribution of the seed layer 162, the first electrode 121, the piezoelectric layer 123, and the second electrode 125 in the lateral resonance suppressing portion K may be formed to be different from a thickness distribution of those in the active portion A formed differently.

As the lateral resonance suppressing portion K is disposed to surround the periphery of the active portion A, in a cross-section of the resonance portion 120 to cross the central portion S, as illustrated in FIG. 2, lateral resonance suppressing portions K may be respectively disposed on both ends of the active portion A.

In the following description, a width W of the lateral resonance suppressing portion K may refer to a width of any one of the two lateral resonance suppressing portions K illustrated in the cross-section, and, for example, may refer to the shortest distance between the active portion A and the expansion portion E.

As illustrated in FIG. 2, a total thickness of the lateral resonance suppressing portion K may be formed to be the same as a total thickness of the active portion A. Therefore, when a thickness of any one of the thin film layers increases in the lateral resonance suppressing portion K, a thickness of another thin film layer, stacked above or below a thin film layer corresponding thereto, may decrease, as compared to the active portion A.

In addition, the lateral resonance suppressing portion K of the present embodiment may be defined as a region in which at least one of the first electrode 121 or the second electrode 125 formed of a metal material is formed to be thinner than the active portion A.

In the present embodiment, the seed layer 162 may be formed such that a portion disposed in the lateral resonance suppressing portion K protrudes toward the first electrode 121 and is thicker than a portion disposed in the active portion A. A total thickness of the first electrode 121 and the seed layer 162 may be formed to be equal to each other, in the lateral resonance suppressing portion K and the active portion A.

Therefore, the first electrode 121 may be formed such that a portion disposed in the lateral resonance suppressing portion K is thinner than a portion disposed in the active portion A.

Since the first electrode 121 has to be disposed on the seed layer 162 even in the lateral resonance suppressing portion K, a distance T2 from which the seed layer 162 protrudes in the lateral resonance suppressing portion K may be less than a thickness T3 of the first electrode 121 disposed in the active portion A.

Due to this configuration, among the plurality of thin film layers, a total thickness of a thin film layer formed of a metal material in the lateral resonance suppressing portion K of the present embodiment may be formed to be thinner than those in the active portion A. In this case, since overall physical properties of the lateral resonance suppressing portion K and the active portion A are different, a resonance frequency of the lateral resonance suppressing portion K may be formed to be different from a resonance frequency of the active portion A. For example, the resonance frequency of the lateral resonance suppressing portion K may be formed in a higher frequency band than the resonance frequency of the active portion A.

Due to the difference in resonant frequencies, lateral waves having different wavelengths may be generated in the lateral resonance suppressing portion K and the active portion A, respectively. Therefore, as lateral waves having different wavelengths interfere with each other, lateral resonance may be suppressed.

Therefore, lateral waves may be effectively limited to minimize generation of noise (e.g., lateral wave noise) due to resonance of the lateral waves.

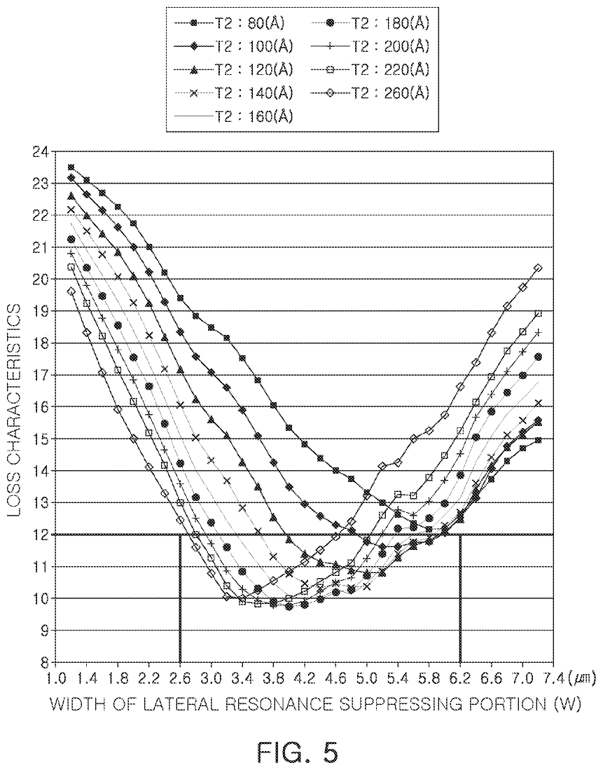

FIG. 5 is a graph measuring loss characteristics according to a width and a thickness of a lateral resonance suppressing portion, and the loss characteristics were measured while increasing a thickness of a seed layer 162 of a lateral resonance suppressing portion K.

In the graph of FIG. 5, measurements were performed on a bulk-acoustic wave resonator having a thickness of a first electrode 121 of 2300 Å and a thickness of a seed layer 162 of 570 Å in an active portion A. In addition, in FIG. 5, an X-axis represents a width W of a lateral resonance suppressing portion K, and a Y-axis represents loss characteristics caused by lateral wave noise. In this case, the loss characteristics caused by lateral wave noise may be defined as the sum of areas of certain bands in which noise is severely generated due to unnecessary resonance, among frequency bands below a resonance frequency in an S-parameter graph of the bulk-acoustic wave resonator. Therefore, as the loss characteristics increase, performance of the bulk-acoustic wave resonator may be deteriorated.

Referring to FIG. 5 together, it can be seen that as the width W of the lateral resonance suppressing portion K increases, the loss characteristics due to the lateral wave noise decreases, and then increases again after passing a pole.

Through various experiments, it was confirmed that, when the loss characteristics due to lateral wave noise was 12 or more, energy loss greatly increased, and effectiveness of the bulk-acoustic wave resonator was reduced. Therefore, in the bulk-acoustic wave resonator according to the present embodiment, a width and a depth of the lateral resonance suppressing portion K may be defined in a range in which the loss characteristics is less than 12.

Considering the range in which the loss characteristics are less than 12 in FIG. 5, a width W of the lateral resonance suppressing portion K may be included in the range of approximately 2.6 μm (microns) to 6.2 μm. For example, when the width W of the lateral resonance suppressing portion K is within the above range, a distance (T2, hereinafter, a protruding distance) at which the seed layer 162 protrudes in the lateral resonance suppressing portion K may be adjusted to have a loss characteristics of less than 12.

Therefore, in the present embodiment, the width W of the lateral resonance suppressing portion K may be formed in a range of approximately 2.6 μm to 6.2 μm.

Also, referring to FIG. 5, when the protrusion distance T2 was 80 Å, the loss characteristics were 12 or more in all ranges, regardless of the width W of the lateral resonance suppressing portion K, and when the protrusion distance T2 was 100 Å, the loss characteristics were measured to be less than 12 in some regions. Therefore, when the protrusion distance T2 is less than 80 Å, the loss characteristics may not be less than 12 even when the width W of the lateral resonance suppressing portion is changed. Therefore, in the bulk-acoustic wave resonator of the present embodiment, the above-described protrusion distance T2 may be formed to be 100 Å or more.

In addition, when the protrusion distance T2 is excessively long, the thickness T3 of the first electrode 121 in the lateral resonance suppressing portion K may be excessively short, and in this case, another spurious resonance may occur.

In consideration of an error in process, in general, the first electrode 121 may be manufactured to have a thickness having a margin of 10%. Therefore, in the bulk-acoustic wave resonator of the present embodiment, the protrusion distance T2 may be formed within 10% of the thickness of the first electrode 121.

As described above, in the present embodiment, since the thickness of the first electrode 121 was formed to be about 2300 Å, the protrusion distance T2 may be formed in the range of 230 Å or less.

Therefore, the protrusion distance T2 of the seed layer 162 in the lateral resonance suppressing portion K may be formed in a range of 100 Å to 230 Å. For this reason, among a plurality of thin film layers constituting a resonance portion 120, thin film layers (e.g., first and second electrodes) formed of a metal material may be formed such that a difference in thickness in the lateral resonance suppressing portion K and the active portion A is in the range of 100 Å to 230 Å.

In the present embodiment, the lateral resonance suppressing portion K may be disposed in a central portion S, in which an entire portion thereof is a vibration active region. However, the present disclosure is not limited thereto, and at least a portion may be configured to be disposed on the expansion portion E if necessary.

The bulk-acoustic wave resonator according to the present embodiment configured as described above may suppress spurious resonance caused by a lateral wave through the lateral resonance suppressing portion K, to minimize noise generated due to lateral wave resonance, and deterioration of resonator performance.

The spurious resonance may be caused by a lateral wave (or a transverse-mode standing wave) generated in the resonance portion 120, to distort or deteriorate resonance performance.

Therefore, in order to minimize unnecessary resonance, the bulk-acoustic wave resonator according to the present embodiment may change properties of a portion related thereto by disposing a lateral resonance suppressing portion K at a boundary between the central portion S generating substantially resonance and the expansion portion E functioning as a frame.

Therefore, since resonant frequencies in the active portion A, the lateral resonance suppressing portion K, and the expansion portion E may be formed to be different from each other, an overall vibration form may be changed. Through this, an amount of change in amplitude within the resonance portion 120 in a vertical direction, according to a distance in a horizontal direction, may be reduced.

Therefore, occurrence of resonance in a horizontal direction at a frequency lower than a resonance frequency, and thus occurrence of noise may be suppressed through the lateral resonance suppressing portion K.

The present disclosure is not limited to the above-described embodiment, and various modifications are possible.

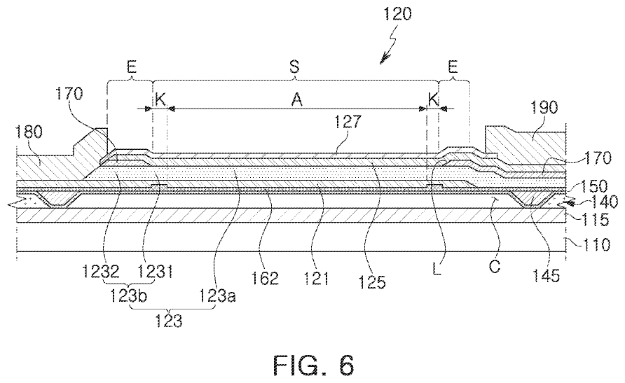

FIGS. 6 to 12 are cross-sectional views schematically illustrating bulk-acoustic wave resonators according to one or more other embodiments of the present disclosure, respectively.

Referring to FIG. 6, in a bulk-acoustic wave resonator according to the present embodiment, an insertion layer 170 may be disposed between a piezoelectric layer 123 and a second electrode 125. Therefore, the piezoelectric layer 123 may be formed to be flat as a whole, and the second electrode 125 may be partially raised to correspond to a shape of the insertion layer 170.

The insertion layer 170 of the present embodiment may have the same shape as that of the above-described embodiment, but only a position in which the insertion layer 170 is stacked may be configured in a different manner. Therefore, an overall appearance of the bulk-acoustic wave resonator according to the present embodiment may be formed, similarly to the bulk-acoustic wave resonator of the above-described embodiment.

In addition, in the bulk-acoustic wave resonator illustrated in the present embodiment, the second electrode 125 may be disposed on an upper surface of the piezoelectric layer 123, and accordingly, the second electrode 125 may be disposed where an extended portion 1232 of the piezoelectric layer 123, as well as an inclined portion 1231 of the piezoelectric layer 123 would be in the above-described embodiment. However, as the piezoelectric layer 123 may be formed to be flat as a whole, where the inclined portion 1231 of the piezoelectric layer 123 would be may be flat as well in the present embodiment.

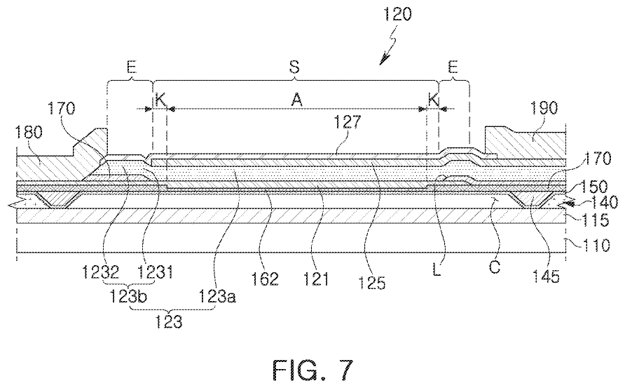

Referring to FIG. 7, in a bulk-acoustic wave resonator according to the present embodiment, a thickness of a seed layer 162 disposed in an expansion portion E may be equal to a thickness of the seed layer 162 disposed in a lateral resonance suppressing portion K. Therefore, a thickness of a first electrode 121 disposed in the expansion portion E may be equal to a thickness of the first electrode 121 disposed in the lateral resonance suppressing portion K.

As described above, an insertion layer 170 may be disposed in the expansion portion E. Therefore, even when the seed layer 162 and the first electrode 121 are formed to have the same thickness in the lateral resonance suppressing portion K, the expansion portion E may be clearly distinguished from the lateral resonance suppressing portion K in the stacked structure, to provide a frame function.

The bulk-acoustic wave resonator according to the present embodiment, in a cross-section of a resonance portion 120 crossing a central portion S, an end portion of the second electrode 125 may be formed only on an upper surface of a piezoelectric portion 123a of a piezoelectric layer 123, and may not be formed on a bent portion 123b. Therefore, the end portion of the second electrode 125 may be disposed along a boundary between the piezoelectric portion 123a and an inclined portion 1231.

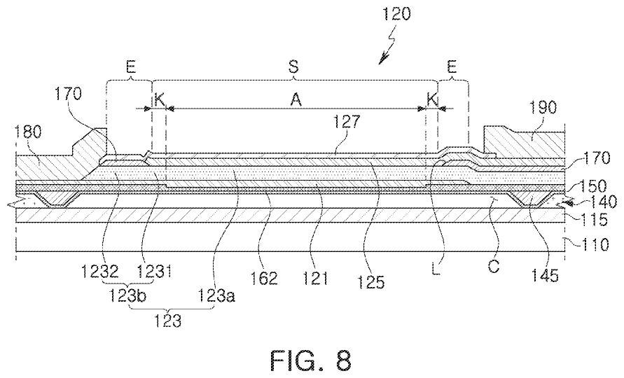

Referring to FIG. 8, a bulk-acoustic wave resonator of the present embodiment may be similar to the bulk-acoustic wave resonator illustrated in FIG. 7, except that an insertion layer 170 is disposed between a piezoelectric layer 123 and a second electrode 125. As such, the insertion layer 170 may be stacked at various positions in an expansion portion E.

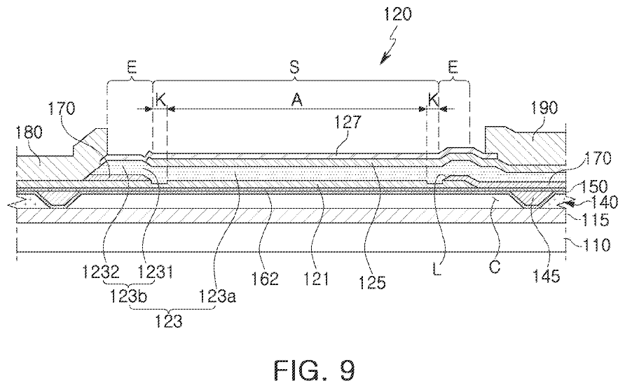

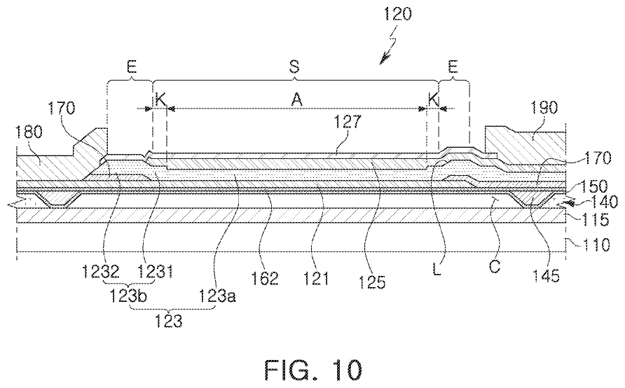

Referring to FIGS. 9 and 10, in a bulk-acoustic wave resonator of the present embodiment, a thickness of a piezoelectric layer 123, rather than a seed layer 162, may increase in a lateral resonance suppressing portion K. In this case, an overall thickness of a first electrode 121, a piezoelectric layer 123, and a second electrode 125 in the lateral resonance suppressing portion K may be the same as those in an active portion A.

Referring to FIG. 9, in the present embodiment, a portion of the piezoelectric layer 123 disposed in the lateral resonance suppressing portion K may protrude toward the first electrode 121, to be thicker than a portion of the piezoelectric layer 123 disposed in the active portion A. Therefore, a portion of the first electrode 121 disposed in the lateral resonance suppressing portion K may be formed to have a thinner thickness than a portion of the first electrode 121 disposed in the active portion A.

Since the first electrode 121 should be disposed below the piezoelectric layer 123 even in the lateral resonance suppressing portion K, a distance at which the piezoelectric layer 123 protrudes in the lateral resonance suppressing portion K may be less than a thickness of the first electrode 121 in the active portion A.

Also, referring to FIG. 10, in the present embodiment, a portion of the piezoelectric layer 123 disposed in the lateral resonance suppressing portion K may protrude toward the second electrode 125, to be thicker than a portion of the piezoelectric layer 123 disposed in the active portion A. Therefore, a portion of the second electrode 125 disposed in the lateral resonance suppressing portion K may be formed to have a thinner thickness than a portion of the second electrode 125 disposed in the active portion A.

In a similar manner to the above-described embodiment, in the bulk-acoustic wave resonator illustrated in FIGS. 9 and 10, a distance at which the piezoelectric layer 123 in the lateral resonance suppressing portion K protrudes toward the first electrode 121 or the second electrode 125 may be in the range of 100 Å to 230 Å, and a width of the lateral resonance suppressing portion K may be in the range of 2.6 μm to 6.2 μm.

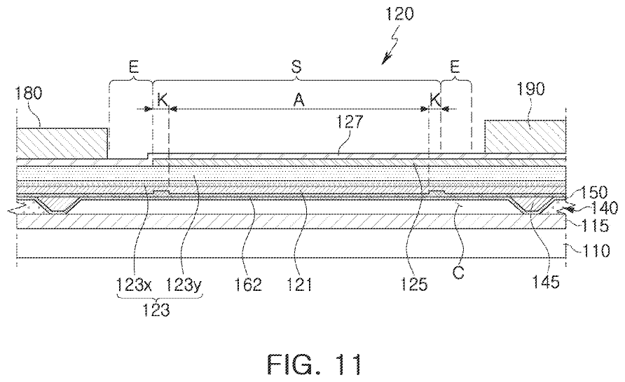

Referring to FIG. 11, in a bulk-acoustic wave resonator of the present embodiment, the aforementioned insertion layer 170 may be omitted. Therefore, a piezoelectric layer 123 and a second electrode 125, stacked on a first electrode 121, may be disposed in parallel with the first electrode 121.

Since the insertion layer 170 may be omitted, in the bulk-acoustic wave resonator of the present embodiment, a stacked structure in an expansion portion E may be the same as that in an active portion A.

Also, in the bulk-acoustic wave resonator of the present embodiment, the piezoelectric layer 123 may include a first piezoelectric layer 123x and a second piezoelectric layer 123y.

The first piezoelectric layer 123x may be stacked on the first electrode 121, and the second piezoelectric layer 123y may be stacked on the first piezoelectric layer 123x. In this case, the first piezoelectric layer 123x and the second piezoelectric layer 123y may be formed of different materials.

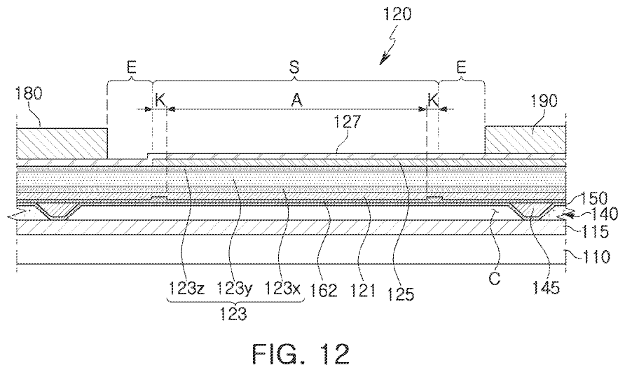

Referring to FIG. 12, a bulk-acoustic wave resonator of the present embodiment may be similar to the bulk-acoustic wave resonator illustrated in FIG. 11, except that a piezoelectric layer 123 may further include a third piezoelectric layer 123z.

The third piezoelectric layer 123z may be stacked on a second piezoelectric layer 123y, and a second electrode 125 may be stacked on the third piezoelectric layer 123z.

In the present embodiment, the third piezoelectric layer 123z may be formed of the same material as a first piezoelectric layer 123x, and may be also formed to have the same thickness as the first piezoelectric layer 123x. However, a configuration of the present disclosure is not limited thereto. For example, the third piezoelectric layer 123z may be formed of a different material and a different thickness, from the first and second piezoelectric layers 123x and 123y.

The piezoelectric layer applied to FIGS. 11 and 12 may be applied to other embodiments described above.

Also, each of the embodiments may be carried out in combination with one or more of the other embodiments.

A bulk-acoustic wave resonator according to the present disclosure may effectively suppress a lateral wave to minimize occurrence of noise due to spurious resonance.

While specific example embodiments have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A bulk-acoustic wave resonator comprising:
a substrate;
a resonance portion comprising a first electrode, a piezoelectric layer, and a second electrode, stacked in this order on the substrate; and
a seed layer disposed below the first electrode,
wherein the resonance portion comprises an active portion disposed in a central portion of the resonance portion, and a lateral resonance suppressing portion disposed to surround the active portion,
wherein a thickness distribution of the seed layer, the first electrode, the piezoelectric layer, and the second electrode in the lateral resonance suppressing portion is different from a thickness distribution in the active portion.

2. The bulk-acoustic wave resonator of claim 1, wherein a thickness of at least one of the first electrode and the second electrode in the lateral resonance suppressing portion is thinner than a thickness of the at least one of the first electrode and the second electrode in the active portion.

3. The bulk-acoustic wave resonator of claim 2, wherein a thickness of the seed layer in the lateral resonance suppressing portion is thicker than a thickness of the seed layer in the active portion.

4. The bulk-acoustic wave resonator of claim 3, wherein the seed layer in the lateral resonance suppressing portion protrudes toward the first electrode, and
wherein a distance from which the seed layer protrudes is 100 Å to 230 Å.

5. The bulk-acoustic wave resonator of claim 3, wherein a width of the lateral resonance suppressing portion is 2.6 μm to 6.2 μm.

6. The bulk-acoustic wave resonator of claim 2, wherein, a thickness of the piezoelectric layer in the lateral resonance suppressing portion is thicker than a thickness of the piezoelectric layer in the active portion.

7. The bulk-acoustic wave resonator of claim 1, wherein the resonance portion further comprises an expansion portion disposed to surround the lateral resonance suppressing portion, and
wherein the expansion portion comprises an insertion layer disposed between the first electrode and the second electrode.

8. The bulk-acoustic wave resonator of claim 7, wherein the insertion layer is disposed between the first electrode and the piezoelectric layer or between the piezoelectric layer and the second electrode.

9. The bulk-acoustic wave resonator of claim 7, wherein a thickness of the seed layer in the lateral resonance suppressing portion is equal to a thickness of the seed layer in the expansion portion.

10. The bulk-acoustic wave resonator of claim 1, wherein the piezoelectric layer comprises a first piezoelectric layer stacked on the first electrode, and a second piezoelectric layer stacked on the first piezoelectric layer, and
wherein the first piezoelectric layer and the second piezoelectric layer are formed of different materials.

11. The bulk-acoustic wave resonator of claim 10, wherein the piezoelectric layer further comprises a third piezoelectric layer stacked on the second piezoelectric layer, and
wherein the third piezoelectric layer is formed of the same material as the first piezoelectric layer.

12. A bulk-acoustic wave resonator comprising:
a substrate; and
a resonance portion comprising a plurality of thin film layers stacked on the substrate,
wherein the resonance portion comprises an active portion disposed in a central portion of the resonance portion, and a lateral resonance suppressing portion disposed to surround the active portion,
wherein an overall thickness of a thin film layer formed of a metal material, among the plurality of thin film layers, in the lateral resonance suppressing portion is thinner than an overall thickness of the thin film layer in the active portion, and
wherein a difference in thickness of the thin film layer is 100 Å to 230 Å.

13. The bulk-acoustic wave resonator of claim 12, wherein the plurality of thin film layers comprise a seed layer and a first electrode stacked on the seed layer, and
wherein the seed layer in the lateral resonance suppressing portion protrudes toward the first electrode.

14. The bulk-acoustic wave resonator of claim 13, wherein an overall thickness of the seed layer and the first electrode in the lateral resonance suppressing portion is equal to an overall thickness of the seed layer and the first electrode in the active portion.

15. The bulk-acoustic wave resonator of claim 12, wherein the plurality of thin film layers comprise a first electrode, a piezoelectric layer, and a second electrode, stacked in this order, and
wherein the piezoelectric layer in the lateral resonance suppressing portion protrudes toward the first electrode or the second electrode.

16. The bulk-acoustic wave resonator of claim 15, wherein an overall thickness of the first electrode, the piezoelectric layer, and the second electrode in the lateral resonance suppressing portion is equal to an overall thickness of the first electrode, the piezoelectric layer, and the second electrode in the active portion.

17. A bulk acoustic wave resonator comprising:
a plurality of layers comprising a seed layer, a first electrode, a piezoelectric layer, and a second electrode disposed in this order in a thickness direction on a substrate,
wherein one or more of the plurality of layers comprises a protrusion in the thickness direction disposed in a lateral resonance suppressing portion, and
wherein the plurality of layers comprise a same thickness in an active portion adjacent to the lateral resonance suppressing portion as in the lateral resonance suppressing portion.

18. The bulk-acoustic wave resonator of claim 17, wherein a thickness of at least one of the first electrode and the second electrode in the lateral resonance suppressing portion is less than a thickness of the at least one of the first electrode and the second electrode in the active portion.

19. The bulk-acoustic wave resonator of claim 17, further comprising an insertion layer disposed between the first electrode and the second electrode in an expansion portion,
wherein the lateral resonance suppressing portion is disposed between the active portion and the expansion portion.

20. The bulk-acoustic wave resonator of claim 19, wherein the lateral resonance suppressing portion width is in a range of about 2.6 μm to 6.2 μm.

21. The bulk-acoustic wave resonator of claim 17, wherein the protrusion is in a range of about 5% to 10% of the thickness of the first electrode.
